(19) United States
(12) Patent Application Publication
(10) Pub. No.: US 2016/0011268 A1
(43) Pub. Date: Jan. 14, 2016

(54) MOTOR FAULT DETECTING METHOD AND MOTOR FAULT DETECTING SYSTEM

(71) Applicant: NATIONAL CHENG KUNG UNIVERSITY, TAINAN CITY (TW)

(72) Inventors: Mi-Ching TSAI, TAINAN CITY (TW); Shao-Kai LIN, TAINAN CITY (TW); Sheng-He WANG, TAINAN CITY (TW)

(21) Appl. No.: 14/609,444

(22) Filed: Jan. 30, 2015

(30) Foreign Application Priority Data
Jul. 10, 2014 (TW) 103123810

(51) Int. Cl. G01R 31/34

(52) U.S. Cl. CPC G01R 31/34

(57) ABSTRACT

A motor fault detecting method and a motor fault detecting system are provided. An electrical frequency and sensing current data of a brushless motor is obtained. An empirical mode decomposition (EMD) is performed on the sensing current data to obtain intrinsic mode functions (IMF). A feature IMF is obtained from the IMFs, in which the feature IMF is feature current data, and a frequency of the feature current data complies with the electrical frequency of the brushless motor. An electrical impedance is calculated according to an input voltage of the brushless motor and the feature current data. The electrical impedance is compared with a reference electrical impedance to determine if the brushless motor is abnormal. The reference electrical impedance is calculated according to training sensing current data of a training brushless motor which is in a healthy state. Accordingly, whether the brushless motor is abnormal is effectively determined.

### RELATED APPLICATIONS

This application claims priority to Taiwan Application Serial Number 103123810 filed Jul. 10, 2014, which is herein incorporated by reference.

### BACKGROUND

1. Field of Disclosure

The present invention relates to a motor fault detecting mechanism. More particularly, the present invention relates to a motor fault detecting method and a motor fault detecting system for determining whether a motor is abnormal according to an impedance.

2. Description of Related Art

With the fast development of technology, a motor is widely used in heavy industry, semiconductor industry, auto industry, etc. In order to detect whether the motor is abnormal, information such as voltage and current of the motor is generally required to be sensed, and then signal processing is performed to achieve such detection. For example, a fast Fourier transform can be used to analyze frequency components of a signal, thereby determining whether the signal is abnormal. However, the fast Fourier transform is suitable for analyzing a periodic and stationary signal, but not suitable for some applications. In addition, a measured signal in the nature may include noises, and the noises may affect an accuracy of the detection. Therefore, it is an issue concerned by people in the art that how to effectively and quickly determine if the motor is abnormal.

### SUMMARY

Embodiments of the invention provide a motor fault detecting method and a motor fault detecting system that can detect whether a motor is abnormal quickly and effectively.

An embodiment of the invention provides a motor fault detecting method for inspecting a health state of a brushless motor. The motor fault detecting method includes the following steps. An electrical frequency of the brushless motor is obtained. Sensing current data of the brushless motor is obtained when the brushless motor is operating. An empirical mode decomposition (EMD) of a Hilbert-Huang transform (HHT) is performed on the sensing current data to obtain intrinsic mode functions (IMFs). A feature IMF is obtained from the IMFs, in which the feature IMF is feature current data, and a frequency of the feature current data complies with the electrical frequency of the brushless motor. At least one electrical impedance is calculated according to an input voltage of the brushless motor and the feature current data. The at least one electrical impedance is compared with a reference electrical impedance to determine whether the brushless motor is abnormal. The reference electrical impedance is calculated according to training sensing current data of a training brushless motor which is in a healthy state.

An embodiment of the invention provides a motor fault detecting system including a brushless motor, a current sensing unit and a processor. The brushless motor includes an inverter and a motor. The current sensing unit is disposed between the inverter and the motor. The processor obtains an electrical frequency of the brushless motor, and obtains sensing current data of the brushless motor through the current sensing unit when the brushless motor is operating. The detecting module performs an empirical mode decomposition (EMD) of a Hilbert-Huang transform (HHT) on the sensing current data to obtain intrinsic mode functions (IMFs), and obtains a feature IMF from the IMFs. The feature IMF is feature current data, and a frequency of the feature current data complies with the electrical frequency of the brushless motor. The processor calculates at least one electrical impedance according to an input voltage of the brushless motor and the feature current data, and compares the at least one electrical impedance with a reference electrical impedance to determine whether the brushless motor is abnormal. The reference electrical impedance is calculated according to training sensing current data of a training brushless motor which is in a healthy state.

In sum, in the motor fault detecting method and the motor fault detecting system provided in the embodiments of the invention, the electrical impedance is calculated by using the IMFs, and therefore whether the brushless motor is abnormal is effectively detected.

### BRIEF DESCRIPTION OF THE DRAWINGS

The invention can be more fully understood by reading the following detailed description of the embodiment, with reference made to the accompanying drawings as follows:

FIG. 1 is a schematic diagram illustrating a motor fault detecting system according to an embodiment;

FIG. 2 is a schematic diagram illustrating sensing current data according to an embodiment;

FIG. 3A to FIG. 3F are schematic diagrams illustrating intrinsic mode functions according to an embodiment;

FIG. 4 is a flow chart illustrating a training stage and a testing stage according to an embodiment; and

FIG. 5 is a flow chart illustrating a motor fault detecting method according to an embodiment.

### DETAILED DESCRIPTION

Specific embodiments of the present invention are further described in detail below with reference to the accompanying drawings, however, the embodiments described are not intended to limit the present invention and it is not intended for the description of operation to limit the order of implementation. Moreover, any device with equivalent functions that is produced from a structure formed by a recombination of elements shall fall within the scope of the present invention. Additionally, the drawings are only illustrative and are not drawn to actual size.

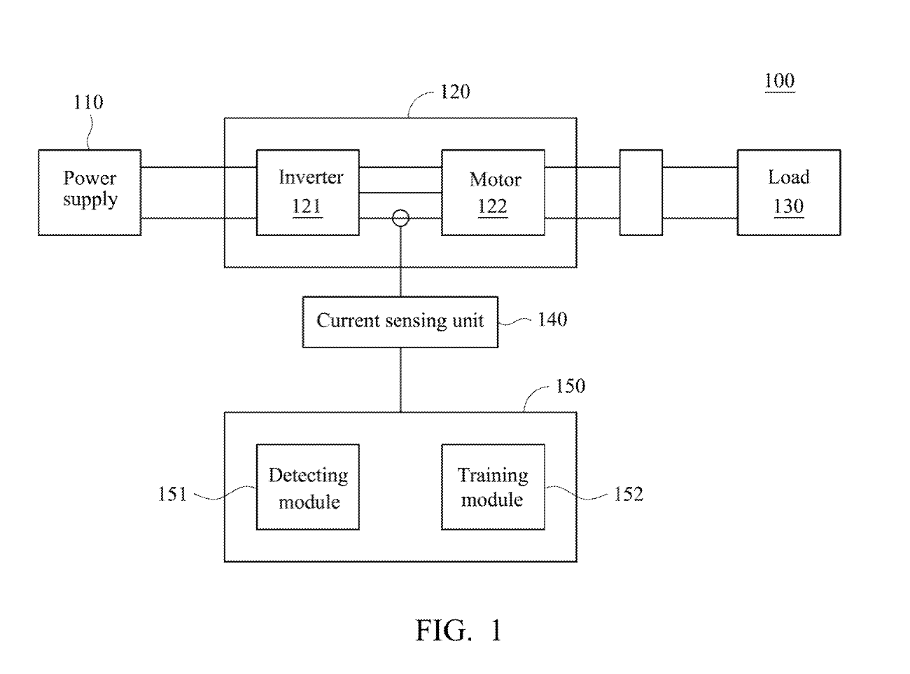

FIG. 1 is a schematic diagram illustrating a motor fault detecting system according to an embodiment. Referring to FIG. 1, a motor fault detecting system 100 includes a power supply 110, a brushless motor 120, a load 130, a current sensing unit 140 and a detecting device 150.

In the embodiment, the power supply 110 provides direct current (DC) power to the brushless motor 120. In another embodiment, the power supply 110 may provide alternating current (AC) power to the brushless motor 120, but the invention is not limited thereto.

The brushless motor 120 includes an inverter 121 and a motor 122. In the embodiments, the inverter 121 is used to convert the DC power into AC power, and to drive the motor 122 according to the AC power. In another embodiment, if the power supply 110 provides AC power, then the brushless motor 120 further includes an converter (not shown) to the convert the AC power into DC power, and the inverter 121 converts the DC power outputted from the converter into AC power. In addition, the motor 122 is connected to a load 130, but the type of the load 130 is not limited in the invention.

The current sensing unit 140 is disposed between the inverter 121 and the motor 122, and used to sense line current on the inverter 121. For example, the current sensing unit 140 is a clamp meter, but the invention is not limited thereto.

The detecting device 150 obtains sensing current data of the brushless motor 120 through the current sensing unit 140 when the brushless motor 120 is operating. For example, the detecting device 150 obtains a current value through the current sensing unit 140 every once in a while. After a period of time, the current values constitute the aforementioned sensing current data. The detecting device 150 determines whether the brushless motor 120 is abnormal according to the sensing current data.

The detecting device 150 includes a detecting module 151 and a training module 152. In an embodiment, the detecting device 150 is implemented as a computer, and the detecting module 151 and the training module 152 are program codes executed by one or more processors (not shown) in the detecting device 150. However, in another embodiment, the detecting module 151 and the training module 152 may be implemented as circuits. The operations of the detecting module 151 and the training module 152 will be described below, but whether the detecting module 151 and the training module 152 are implemented as software or hardware is not limited in the invention. The invention does not limit the product or electrical device which the detecting device 150 is implemented as, either. In addition, in an embodiment, the detecting device 150 further includes a screen, and if the brushless motor 120 is in an abnormal state, the screen shows a corresponding message. Accordingly, a user can monitor the state of the brushless motor 120.

First, the detecting module 151 performs an empirical mode decomposition (EMD) of a Hilbert-Huang transform (HHT) on the sensing current data to obtain intrinsic mode functions (IMFs). People in the art should be able to understand the content of the HHT and the EMD, and thus the content of the HHT and the EMD will not be described in detail herein. Basically, each IMF has to comply with two criteria. In the first criterion, the number of local extrema and the number of zero-crossings has to either equal or differ at most by one. In the second criterion, at any point of the IMF, the mean value of the envelope defined by the local maxima and the envelope defined by the local minima is zero. However, in the premise of complying the two criteria, the EMD can be modified in a variety of ways, and the invention is not limited to the specific algorithm of the EMD.

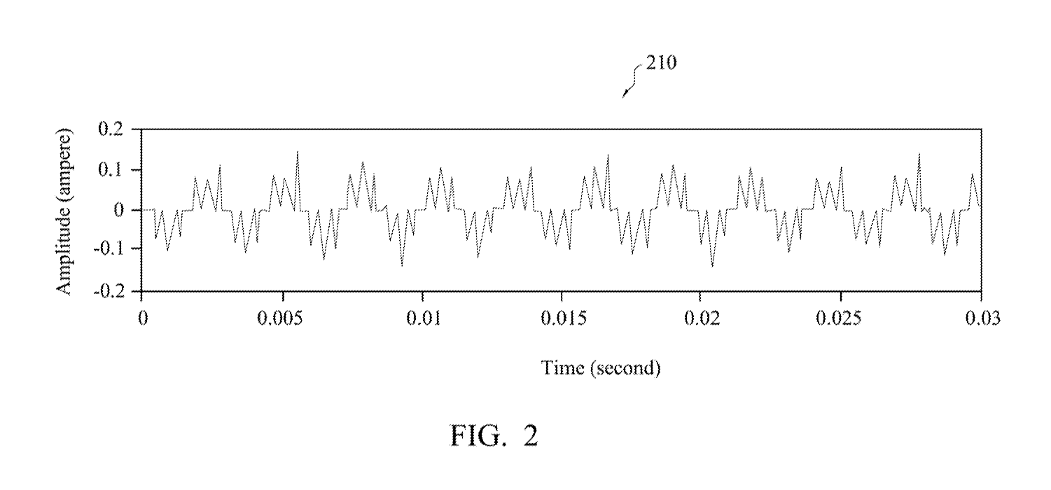

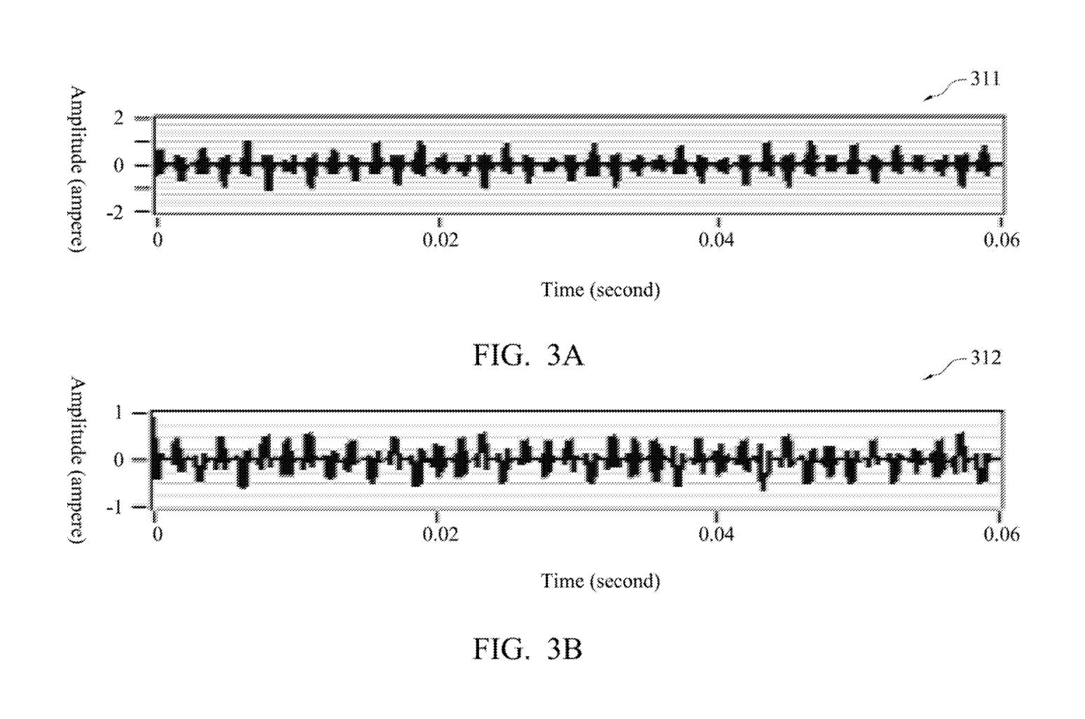

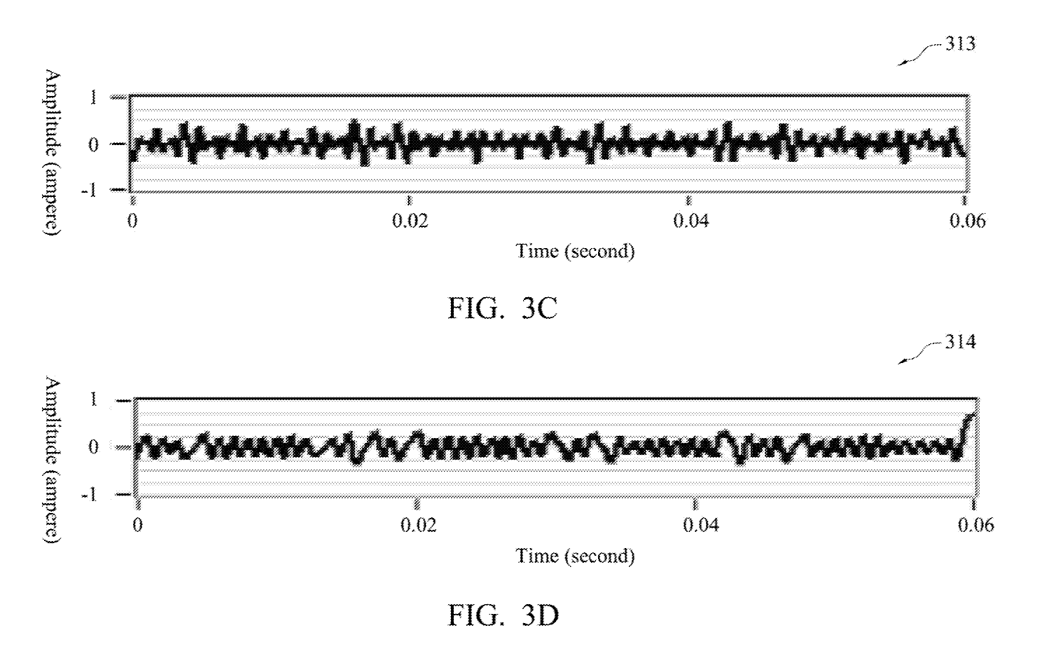

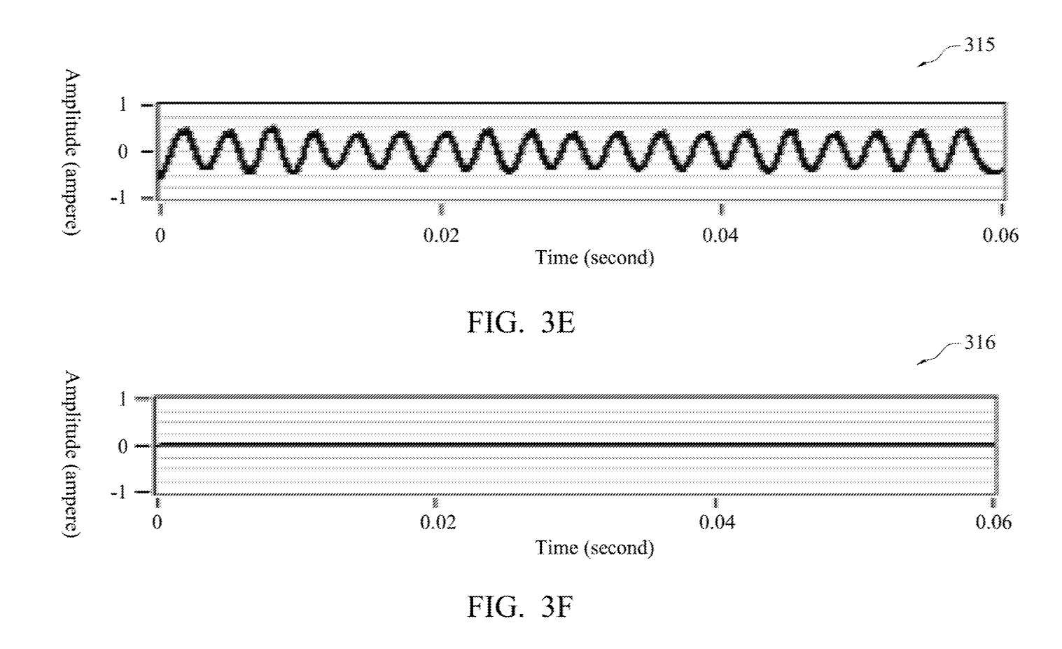

FIG. 2 is a schematic diagram illustrating sensing current data according to an embodiment. FIG. 3A to FIG. 3F are schematic diagrams illustrating intrinsic mode functions according to an embodiment. In the embodiment of FIG. 2 and FIG. 3A to FIG. 3F, the wave form of sensing current data 210 is a six step square wave including noises. After the EMD is performed, the detecting module 151 obtains IMFs 311 to 315 and a residual function 316. However, in other embodiments, the wave form of the sensing current data 210 may also be a sine wave or another type of wave, but the invention is not limited thereto.

On the other hand, the detecting module 151 also obtains an electrical frequency of the brushless motor 120. In an embodiment, the detecting module 151 may calculate the electrical frequency according to a rotational speed and the number of poles of the brushless motor 120. For example, the detecting module 151 may obtain the electrical frequency according to the following equation (1), in which f denotes the electrical frequency of the brushless motor 120; p denotes the number of poles; ω denotes the rotational speed, and the unit thereof is radius per minute (RPM). In another embodiment, the electrical frequency of the brushless motor 120 may be calculated by another electrical device and then transmitted to the detecting module 151.

$$f = \frac{p \cdot ω}{120} \qquad ( 1 )$$

After obtaining the electrical frequency of the brushless motor 120, the detecting module 151 obtains a feature IMF from the IMFs 311 to 315 according to the electrical frequency. The feature IMF is feature current data, and a frequency of the feature current data complies with the electrical frequency of the brushless motor 120. In other words, the frequency of the feature IMF is equal to the main frequency of the brushless motor 120. For example, the detecting module 151 may perform a time-frequency transform on each of the IMFs 311 to 315 to obtain frequency information of the IMFs 311 to 315, and then select the feature IMF according to the frequency information and the electrical frequency of the brushless motor 120. The time-frequency transform may be a Fourier transform, a Hilbert transform or another similar transform, which is not limited in the invention. To be specific, if the Hilbert transform is used, then each IMF (denoted as Cⱼ(t) below) is represented as the following equation (2):

$${C}_{j} ( t ) = RP [ {a}_{j} ( t ) {e}^{i 2 π \int {f}_{j} ( t ) d t} ] \qquad ( 2 )$$

where j denotes the number of the IMFs; t denotes time; RP[ ] denotes the calculation of a real part; aⱼ(t) denotes an instant amplitude function; and fⱼ(t) denotes an instant frequency function. If the time t is substituted into the instant amplitude function aⱼ(t), then an instant amplitude of the IMF can be obtained, and an instant frequency of the IMF can be obtained by substituting the time t into the instant frequency function fⱼ(t). The right-hand side of the equation (2) is also called a transforming function herein. From another aspect, the sensing current data 210 can be represented as the following equation (3), in which signal(t) denotes the sensing current data 210; n denotes the number of the IMFs; and r(t) denotes the residual function 316.

$$signal ( t ) = {\sum }_{j}^{n} {C}_{j} ( t ) + r ( t ) \qquad ( 3 )$$

After the Hilbert transform is performed, the detecting module 151 substitutes different t into the instant frequency function fⱼ(t) to obtain multiple instant frequencies, and obtains an average frequency of the instant frequencies. For example, in the embodiments of FIG. 3A to FIG. 3F, the average frequency of the IMF 311 is relatively higher; and the average frequency of the IMF 315 is relatively lower. Then, the detecting module 151 compares the electrical frequency of the brushless motor 120 with the average frequencies of the IMFs 311 to 315 to obtain the feature IMF. In general, one of the IMFs has the average frequency which is equal or close to the electrical frequency of the brushless motor 120 because the IMFs 311 to 315 are generated according to the sensing current data 210 of the brushless motor 120. In an embodiment, the detecting module 151 finds an IMF having the average frequency which is identical to the electrical frequency of the brushless motor 120, or is differed from the electrical frequency by less than a threshold, and the found IMF is taken as the feature IMF. It is assumed that the IMF 315 is the feature IMF herein.

Then, the detecting module 151 calculates at least one electrical impedance according to an input voltage of the brushless motor 120 and the aforementioned feature current data. Herein, the input voltage of the brushless motor 120 is referred to a DC voltage provided by the power supply 110. In the embodiment, the detecting module 151 obtains an instant amplitude of the IMF 315 according to the aforementioned instant amplitude function aⱼ(t), and divides the input voltage of the brushless motor 120 by the instant amplitude to obtain the electrical impedance as shown in the following equation (4):

$${Z}_{e} ( t ) = \frac{{V}_{source} ( t )}{amp [ {I}_{char} ( t ) ]} = \frac{{V}_{source} ( t )}{amp \{ RP [ {a}_{char} ( t ) {e}^{i 2 π \int {f}_{char} ( t ) d t} ] \}} = \frac{{V}_{source} ( t )}{{a}_{char} ( t )} \qquad ( 4 )$$

wherein Ze(t) denotes the electrical impedance; V_{source}(t) denotes the input voltage of the brushless motor 120; amp[ ] denotes a function for calculating the amplitude; a_{char}(t) denotes the instant amplitude function corresponding to the feature IMF 315; and f_{char}(t) denotes the instant frequency function corresponding to the feature IMF 315.

It is worth mentioning that, the sensing current data 210 in FIG. 2 has lots of noises. If the sensing current data 210 is used to calculate the impedance of the brushless motor 120, then the impedance cannot represent the state of the brushless motor 120 accurately. However, the IMF 315 has less noises and the frequency thereof is equal to the electrical frequency of the brushless motor 120; and therefore the calculated impedance is more capable of representing the state of the brushless motor 120 even though the IMF 315 is not a six step square wave.

Generally, the electrical impedance of a brushless motor which is in a healthy state keeps in a certain range, but the electrical impedance of an abnormal brushless motor may change rapidly. Therefore, the detecting module 151 then compare the calculated electrical impedance with a reference electrical impedance to determine whether the brushless motor 120 is abnormal, in which the reference electrical impedance is calculated according to training sensing current data of at least one training brushless motor which is in a healthy state. For example, similar to the structure of FIG. 1, but the brushless motor 120 is replaced by a healthy training brushless motor. A rotational speed of the training brushless motor is equal to the rotational speed of the brushless motor 120, and the training sensing current data is obtained through the current sensing unit 140. The training module 152 calculates an electrical impedance of the training brushless motor according to the training sensing current data, and calculates the reference electrical impedance according to the electrical impedance of the training brushless motor through a machine learning algorithm or a statistic-relative algorithm. However, the invention does not limit which machine learning algorithm or which statistic-relative algorithm is used. If a difference between the electrical impedance of the brushless motor 120 and the reference electrical impedance is large, then the brushless motor 120 might be abnormal. In an embodiment, if the difference between the electrical impedance of the brushless motor 120 and the reference electrical impedance is larger than a threshold, or a ratio of the two is out of range, then it means that the brushless motor 120 is abnormal.

In another embodiment, the detecting module 151 calculates corresponding electrical impedances at several sampling time points (i.e. the number of the electrical impedance Ze(t) of the brushless motor 120 is greater than 1). In the operation of comparing the electrical impedance with the reference electrical impedance, the detecting module 151 calculates a root mean square impedance of the electrical impedances, and compares the root mean square impedance with the reference electrical impedance to determine whether the brushless motor 120 is abnormal. Note that the detecting module 151 can arbitrarily decides the number of the sampling time points, which is not limited in the invention. Moreover, the detecting module 151 may also repeat the calculation of the root mean square impedance, and compare the average value of the root mean square impedances with the reference electrical impedance.

In an embodiment, the training module 152 calculates the reference electrical impedance according to the way of calculating the aforementioned root mean square impedance. In detail, training module 152 calculates the electrical frequency of the training brushless motor according to a rotational speed and the number of poles of the training brushless motor. The training module 152 also performs the EMD of the HHT on the training sensing current data to obtain training IMFs (see equation (3) discussed above). The training module 152 also obtains a training feature IMF from the training IMFs. The training feature IMF is training feature current data, and a frequency of the training feature current data complies with the electrical frequency of the training brushless motor. Finally, the training module 152 calculates several training electrical impedances according to the input voltage of the training brushless motor and the training feature current data, and generates the reference electrical impedance according to a root mean square impedance of the training electrical impedances. However, the calculations of the EMD, the IMFs, and the electrical impedances have been described in detail above, and therefore they will not be repeated.

In an embodiment, there are more than one training brushless motors, and the training brushless motors have identical rotational speeds and identical numbers of poles. For each of the training brushless motors, the training module 152 obtains the corresponding root mean square impedance. The training module 152 may calculates an average value of the root mean square impedances as the reference electrical impedance.

In addition, training module 152 may also perform a test of gauge repeatability and reproducibility (GR&R) to determine whether a training stage is finished. In general, after the test of GR&R is performed, the training module 152 obtains a precision tolerance ratio (P/T ratio). If the P/T ratio is smaller than a threshold (e.g. 30%), it means the training result is acceptable; if not, the training module 152 re-obtains the training sensing current data, and re-calculates the reference electrical impedance.

On the other hand, because the rotational speed of the training brushless motor is identical to the rotational speed of the brushless motor 120, the calculated electrical frequencies of the motors are the same. Therefore, after the EMD is performed, the detecting module 151 and the training module 152 obtains the feature IMF having the same frequency. In an embodiment, the training module 152 obtains a training number of the training feature IMF among the training IMFs, and transmits the training number to the detecting module 151. The detecting module 151 finds the feature IMF from the IMFs according to the training number. For example, in the embodiment of FIG. 2, the training number is five, and therefore the detecting module 151 directly obtains the fifth IMF 315. As a result, the detecting module 151 does not need to perform the time-frequency transform, and not need to calculate the frequency of each IMF, either.

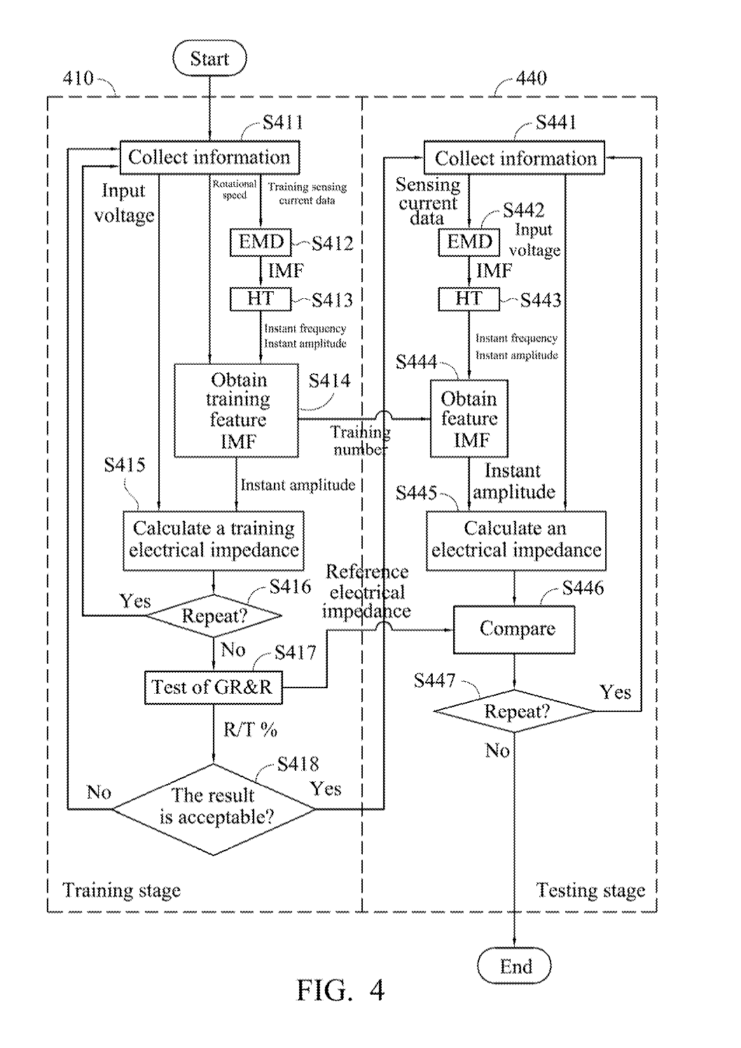

FIG. 4 is a flow chart illustrating a training stage and a testing stage according to an embodiment. The flow chart of FIG. 4 is divided into a training stage 410 and a testing stage 440. Each step of the training stage 410 is performed by the training module 152, and each step of the testing stage 440 is performed by the detecting module 151, which will not be repeated.

In a step S411, information such as input voltage, a rotational speed and training sensing current data of the training brushless motor is collected. In a step S412, the EMD is performed on the training sensing current data to obtain training IMFs. In a step S413, the Hilbert transform is performed on the training IMFs to obtain instant frequencies and instant amplitudes. In a step S414, the electrical frequency of the training brushless motor is calculated according to the rotational speed and the number of the poles of the training brushless motor, and one of the training IMF is taken as the training feature IMF. In a step S415, a training electrical impedance or a root mean square impedance is calculated according to the instant amplitudes of the training feature IMF and the input voltage. In a step S416, it is determined whether to repeat the steps S411 to S415. For example, the training module 152 may repeat the steps S411 to S415 for several times, thereby obtaining several root mean square impedances. In a step S417, the test of GR&R is performed to generate a PIT ratio. In a step S418, whether the result is acceptable is determined. To be specific, if the P/T ratio is smaller than a threshold, then the result is acceptable; but if the P/T ratio is greater or equal to the threshold, the result is not acceptable.

In a step S441, information such as sensing current data, a rotational speed and an input voltage of the brushless motor 120 is collected. In a step S442, EMD is performed on the sensing current data to obtain IMFs. In a step S443, the Hilbert transform is performed on the IMFs to obtain instant frequencies and instant amplitudes. In a step S444, a feature IMF is obtained from the IMFs according to the training number. In a step S445, an electrical impedance is calculated according to the input voltage and the instant amplitude of the feature IMF. In a step S446, the calculated electrical impedance is compared with the reference electrical impedance so as to determine whether the brushless motor 120 is abnormal. In a step S447, it is determined whether to repeat the steps S441 to S446. For example, the training module 152 may repeat the steps S441 to S446 for several times to confirm whether the brushless motor 120 is abnormal.

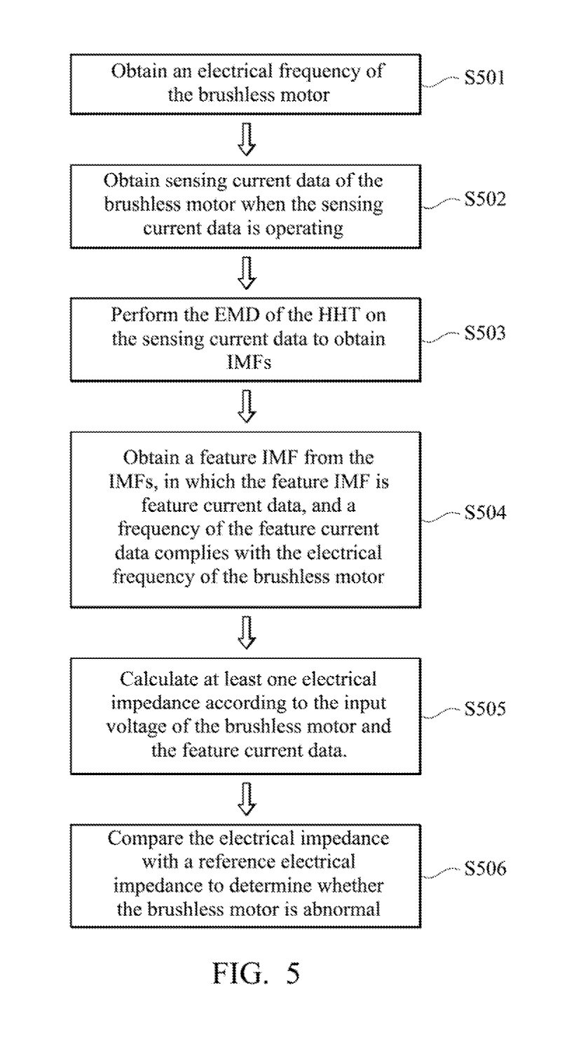

Referring to FIG. 5, FIG. 5 is a flow chart illustrating a motor fault detecting method according to an embodiment. In a step S501, an electrical frequency of the brushless motor is obtained. In a step S502, sensing current data of the brushless motor is obtained when the sensing current data is operating. In a step S503, the EMD of the HHT is performed on the sensing current data to obtain IMFs. In a step S504, a feature IMF is obtained from the IMFs, in which the feature IMF is feature current data, and a frequency of the feature current data complies with the electrical frequency of the brushless motor. In a step S505, at least one electrical impedance is calculated according to the input voltage of the brushless motor and the feature current data. In a step S506, the electrical impedance is compared with a reference electrical impedance to determine whether the brushless motor is abnormal. However, each step of FIG. 5 has been described in detail above, and therefore they will not be repeated. Note that each step of FIG. 5 can be implemented as program codes or circuits, which is not limited in the invention. In addition, the method of FIG. 5 can be performed with the aforementioned embodiments, or performed independently.

Although the present invention has been described in considerable detail with reference to certain embodiments thereof, other embodiments are possible. Therefore, the spirit and scope of the appended claims should not be limited to the description of the embodiments contained herein. It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A motor fault detecting method for inspecting a health state of a brushless motor, the motor fault detecting method comprising:
obtaining an electrical frequency of the brushless motor;
obtaining sensing current data of the brushless motor when the brushless motor is operating;
performing an empirical mode decomposition (EMD) of a Hilbert-Huang transform (HHT) on the sensing current data to obtain a plurality of intrinsic mode functions (IMFs);
obtaining a feature IMF from the IMFs, wherein the feature IMF is feature current data, and a frequency of the feature current data complies with the electrical frequency of the brushless motor;
calculating at least one electrical impedance according to an input voltage of the brushless motor and the feature current data; and
comparing the at least one electrical impedance with a reference electrical impedance to determine whether the brushless motor is abnormal, wherein the reference electrical impedance is calculated according to training sensing current data of at least one training brushless motor which is in a healthy state.

2. The motor fault detecting method of claim 1, wherein the number of the at least one electrical impedance is greater than 1, and the electrical impedances are respectively corresponding to a plurality of sampling time points, and the operation of comparing the at least one electrical impedance with the reference electrical impedance comprises:
calculating a root mean square impedance of the electrical impedances; and
comparing the root mean square impedance with the reference electrical impedance to determine whether the brushless motor is abnormal,
wherein the operation of obtaining the electrical frequency of the brushless motor comprises:
calculating the electrical frequency of the brushless motor according to a rotational speed of the brushless motor and the number of poles of the brushless motor.

3. The motor fault detecting method of claim 2, further comprising:
calculating an electrical frequency of the at least one training brushless motor according to a rotational speed of the at least one training brushless motor and the number of poles of the at least one training brushless motor;
obtaining the training sensing current data of the at least one training brushless motor;
performing the EMD of the HHT on the training sensing current data to obtain a plurality of training IMFs;
obtaining at least one training feature IMF from the training IMFs, wherein the at least one training feature IMF is training feature current data, and a frequency of the training feature current data complies with the electrical frequency of the at least one training brushless motor;
calculating a plurality of training electrical impedances according to an input voltage of the at least one training brushless motor and the training feature current data; and
generating the reference electrical impedance according to at least one root mean square impedance of the training electrical impedances.

4. The motor fault detecting method of claim 3, wherein the number of the at least one training brushless motor is greater than 1, and the number of the at least one root mean square impedance is greater than 1, and each of the training brushless motors has the corresponding root mean square impedance, and the operation of generating the reference electrical impedance according to the at least one root mean square impedance of the training electrical impedances comprises:
calculating an average value of the root mean square impedances to generate the reference electrical impedance.

5. The motor fault detecting method of claim 3, wherein the operation of obtaining the at least one training feature IMF from the training IMFs comprises:
performing a Hilbert transform on each of the training IMFs to obtain a plurality of transforming functions;
obtaining a plurality of instant frequencies of each of the transforming functions, and obtaining an average frequency of the instant frequencies; and
comparing the electrical frequency of the at least one training brushless motor with the average frequency of each of the transforming functions, thereby obtaining the at least one training feature IMF.

6. The motor fault detecting method of claim 5, further comprising:
obtaining a training number of the at least one training feature IMF among the training IMFs,
wherein the operation of the obtaining the feature IMF from the IMFs comprises:
obtaining the feature IMF according to the training number.

7. A motor fault detecting system, comprising:
a brushless motor comprising an inverter and a motor;
a current sensing unit disposed between the inverter and the motor; and
a processor configured to obtain an electrical frequency of the brushless motor, and obtain sensing current data of the brushless motor through the current sensing unit when the brushless motor is operating, and perform an empirical mode decomposition (EMD) of a Hilbert-Huang transform (HHT) on the sensing current data to obtain a plurality of intrinsic mode functions (IMFs), and obtain a feature IMF from the IMFs, wherein the feature IMF is feature current data, and a frequency of the feature current data complies with the electrical frequency of the brushless motor,
wherein the processor is configured to calculate at least one electrical impedance according to an input voltage of the brushless motor and the feature current data, and compare the at least one electrical impedance with a reference electrical impedance to determine whether the brushless motor is abnormal, wherein the reference electrical impedance is calculated according to training sensing current data of at least one training brushless motor which is in a healthy state.

8. The motor fault detecting system of claim 7, where the number of the at least one electrical impedance is greater than 1, and the electrical impedances are respectively corresponding to a plurality of sampling time points; and
the processor is further configured to calculate the electrical frequency of the brushless motor according to a rotational speed of the brushless motor and the number of poles of the brushless motor, and calculate a root mean square impedance of the electrical impedances, and compare the root mean square impedance with the reference electrical impedance to determine whether the brushless motor is abnormal,

9. The motor fault detecting system of claim 8, wherein the processor is further configured to calculate an electrical frequency of the at least one training brushless motor according to a rotational speed of the at least one training brushless motor and the number of poles of the at least one training brushless motor;
the processor is further configured to obtain the training sensing current data of the at least one training brushless motor, and perform the EMD of the HHT on the training sensing current data to obtain a plurality of training IMFs, and obtain at least one training feature IMF from the training IMFs, wherein the at least one training feature IMF is training feature current data, and a frequency of the training feature current data complies with the electrical frequency of the at least one training brushless motor; and
the processor is further configured to calculate a plurality of training electrical impedances according to an input voltage of the at least one training brushless motor and the training feature current data, and generate the reference electrical impedance according to at least one root mean square impedance of the training electrical impedances.

10. The motor fault detecting system of claim 9, wherein the number of the at least one training brushless motor is greater than 1, and the number of the at least one root mean square impedance is greater than 1, and each of the training brushless motors has the corresponding root mean square impedance; and
the processor is further configured to calculate an average value of the root mean square impedances to generate the reference electrical impedance.

11. The motor fault detecting system of claim 9, wherein the processor is further configured to perform a Hilbert transform on each of the training IMFs to obtain a plurality of transforming functions, and obtain a plurality of instant frequencies of each of the transforming functions, and obtain an average frequency of the instant frequencies, and compare the electrical frequency of the at least one training brushless motor with the average frequency of each of the transforming functions, thereby obtaining the at least one training feature IMF.

12. The motor fault detecting system of claim 11, wherein the processor is further configured to obtain a training number of the at least one training feature IMF among the training IMFs, and to obtain the feature IMF from the IMFs according to the training number.
